(19) United States
(12) Patent Application Publication
(10) Pub. No.: US 2026/0213518 A1
(43) Pub. Date: Jul. 23, 2026

(54) CURRENT SENSING TECHNIQUE FOR AN ACTIVE COMMUTATION STRATEGY OF A HYBRID DC CIRCUIT BREAKER

(71) Applicant: Florida State University Research Foundation, Inc., Tallahassee, FL (US)

(72) Inventors: Qichen Yang, Tallahassee, FL (US); Karl Schoder, Tallahassee, FL (US)

(21) Appl. No.: 19/453,563

(22) Filed: Jan. 20, 2026

Related U.S. Application Data
(60) Provisional application No. 63/746,797, filed on Jan. 17, 2025.

(51) Int. Cl. H02H 1/00; G01R 31/52; H02H 3/08

(52) U.S. Cl. CPC H02H 1/0061; G01R 31/52; H02H 3/08

(57) ABSTRACT

A circuit system of the present disclosure comprises a voltage source coupled to a power circuit, wherein the power circuit includes a fault management system having a mechanical switch that is triggered in response to a fault condition; and the power circuit further including a fault current commutation circuit having one or more nonlinear inductors in series with the fault management system, a pre-charged capacitor insertion circuit, and a controller configured to sample a voltage across one of the one or more nonlinear inductors and supply a gating signal to the pre-charged capacitor insertion circuit, wherein the controller causes the gating signal to activate when the sampled voltage rises from a negative value to approximately 0 or drops from a positive value to approximately 0.

### CROSS-REFERENCE TO RELATED APPLICATION

This application claims priority to co-pending U.S. provisional application entitled, “Current Sensing Technique for an Active Commutation Strategy of a Hybrid DC Circuit Breaker,” having application No. 63/746,797, filed Jan. 17, 2025, which is entirely incorporated herein by reference.

### STATEMENT REGARDING FEDERALLY SPONSORED RESEARCH OR DEVELOPMENT

This invention was made with government support under DE-AR0001113 awarded by the USDOE Advanced Research Projects Agency-Energy (ARPA-E). The government has certain rights in the invention.

### BACKGROUND

Medium voltage DC (MVDC) power systems are a promising solution for various applications due to their high power density, flexibility, and robustness. However, MVDC systems suffer from short-circuit fault management. To overcome this issue, a hybrid DC circuit breaker (e.g., the EDISON breaker) with a piezoelectric actuated fast mechanical switch, a sequential metal oxide varistor insertion circuitry, and nonlinear inductor-based fault current commutation circuitry has been developed.

For example, Yang et al. presented a nonlinear inductor-based fault current commutation strategy, where a voltage source in the form of a pre-charged capacitor is inserted, in order to extinguish fault current as fast as possible and achieve arc-less opening of the fast mechanical switch. See Yang et al., “Analysis, Modeling, and Experiments of a Nonlinear Inductor-Based Fault Current Commutation Strategy for a Hybrid DC Circuit Breaker,” IEEE Trans. Transp. Electrification (August 2023). The nonlinear inductor circuitry not only limits the rate of current change through the mechanical switch but also provides the current sensing to allow generating gating signals in the fault current commutation circuit (FC3). As the current through the mechanical switch is regulated to remain around zero, the current needs to be measured and fed into a controller of the switches in the fault current commutation circuit (FC3). However, it is challenging to measure the current accurately with an off-the-shelf current sensor. Thus, there is a need for an improved current sensing technique in short-circuit fault management of MVDC power systems.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 shows a circuit diagram of a hybrid DC circuit breaker with exemplary fault current commutation circuitry in accordance with various embodiments of the present disclosure.

FIGS. 2A-2B show a variation of current flowing through a fault management system under the exemplary fault current commutation circuitry of FIG. 1.

FIG. 3 shows a circuit diagram of an exemplary voltage based current sensing mechanism in accordance with various embodiments of the present disclosure.

FIGS. 4A-4D shows simulation results of an exemplary fault current commutation process in accordance with various embodiments of the present disclosure.

### DETAILED DESCRIPTION

The present disclosure describes various embodiments of systems and related methods for improved current sensing techniques in short-circuit fault management of medium voltage DC (MVDC) power systems.

Generally, for a fault management systems (FMS), the current is regulated to remain around zero. As such, the current needs to be measured and fed into a controller of FMS switches in the fault current commutation circuit (FC3). However, it is challenging to measure the current accurately with state of the art current sensing techniques. To address this problem, an exemplary current sensing technique of the present disclosure samples a voltage across a nonlinear inductor of the FC3 circuit that is a function of the current. Thus, in accordance with various embodiments, it is not necessary to measure the FMS current continuously as voltage moments across the nonlinear inductor are indicative of when the FMS current goes through concerned limits of the fault state of the underlying circuitry. As such, the inductance and the voltage of the innovative nonlinear inductor are functions of the FMS current and the response of the voltage to the current is very fast. In particular, the measurand quantity for sensing current is the voltage across the nonlinear inductor of the FC3 circuit, which depends on the saturation phenomenon of the magnetic core of the nonlinear inductor.

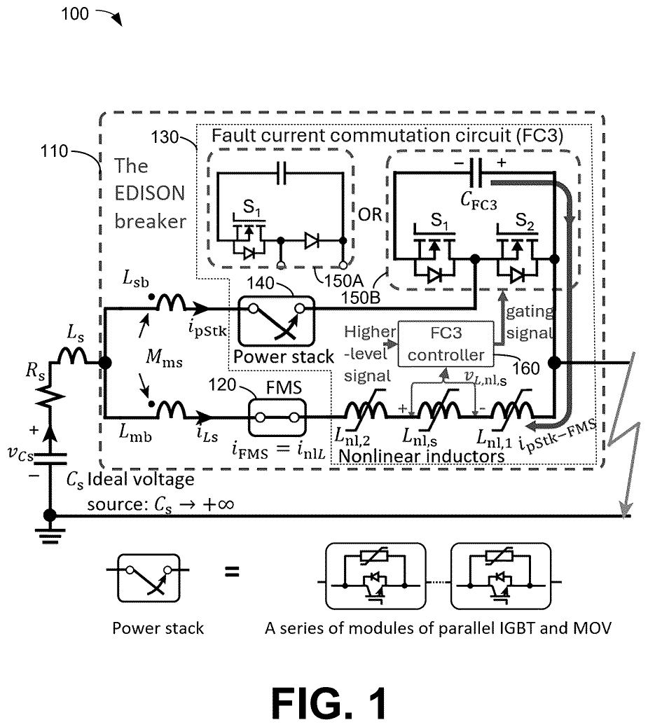

Referring now to FIG. 1, an exemplary diagram of a hybrid EDISON DC circuit breaker with an active fault current commutation strategy, in accordance with various embodiments of the present disclosure, is shown. The overall circuit 100 includes a voltage source v and related capacitance Cₛ, resistance Rₛ, and inductance Lₛ components that are coupled to hybrid DC circuit breaker (EDISON circuit breaker) 110 components which include inductance elements L_{sb}, L_{mb}, fault management system (FMS) having a mechanical switch 120 that is triggered and opened in response to a fault condition, and a fault current commutation circuitry (FC3) 130. In various embodiments, the FC3 includes a power stack 140 (e.g., a series of modules of parallel insulated-gate bipolar transistors (IGBT) and/or metal oxide varistors (MOV)), nonlinear inductors in series (L_{nl,2}, L_{nl,s}, L_{nl,1}) with the mechanical switch 120, a pre-charged capacitor insertion circuit 150A or 150B, and an exemplary FC3 controller 160 that is configured with current sensing technologies of the present disclosure that sample a voltage across the nonlinear inductor L_{nl,s}. In various embodiments, the pre-charged capacitor insertion circuit 150A or 150B includes one or more MOSFET switches (e.g., S₁, S₂), diode(s), and/or capacitor C_{FC3} components.

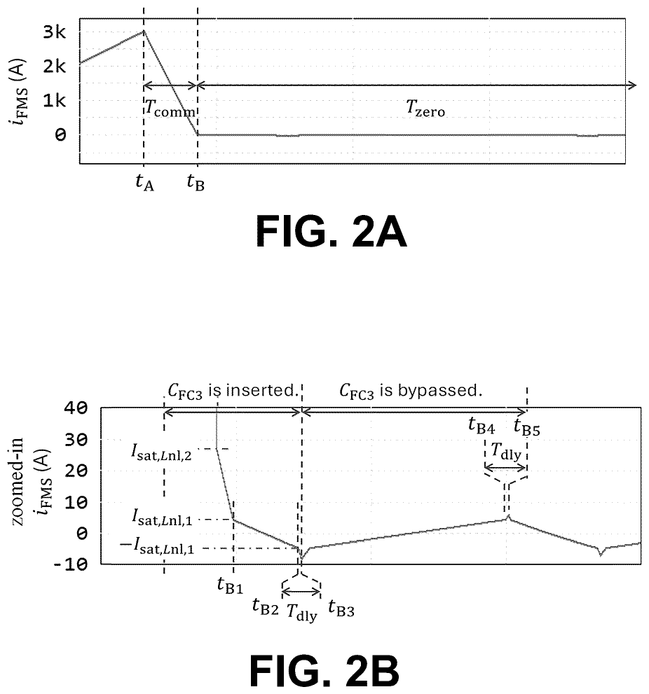

Under an exemplary fault current commutation strategy, the current through the mechanical switch 120 and the nonlinear inductor L_{nl,s} during the commutation process is illustrated in FIGS. 2A-2B. After a short-circuit fault occurs, the mechanical switch 120 in FIG. 1 is still closed and the IGBTs in the power stack 140 are open. Therefore, the current through the mechanical switch 120 continues increasing, as shown in the segment before t_{A} in FIG. 2A. After the fault is detected and the breaker 110 receives the tripping (or triggering) signal, the IGBTs in the power stack 140 are turned on. Since S₁ in the FC3 is kept in the ON state before tripping, the pre-charged C_{FC3} in FIG. 1 starts to discharge and the discharge current, i_{pStk-FMS}, in FIG. 1, cancels out the fault current through the mechanical switch 120. Furthermore, in the segment between t_{A} and t_{B}, i.e., T_{comm}, in FIG. 2A, the current through the mechanical switch 120 decreases. The nonlinear inductors (L_{nl,2}, L_{nl,s}, L_{nl,1}) are saturated deeply during the T_{comm} period, and, therefore, their inductance is negligible and does not impact the commutation speed. When i_{FMS} reaches the linear region of any nonlinear inductor, i.e., the segment after the or the period Tzero in FIG. 2A, active control for i_{FMS} starts.

In the T_{zero} period, the nonlinear inductors provide the current sensing results to the FC3 controller 160 and suppress the switching frequency. Two different types of inductors are used: L_{nl,1} and L_{nl,s} in FIG. 1, which have the same saturation current level, i.e., I_{sat,Lnl,1}, and it is lower than that of L_{nl,2}, i.e., I_{sat,Lnl,2}. When C_{FC3} is inserted (i.e., S₁ is ON), IFMS decreases, as shown by the period t_{A}-t_{B3} in FIG. 2B. When i_{FMS} is lower than the negative saturation level of L_{nl,1} (t_{B2} in FIG. 2B) and L_{nl,1},s, voltage across L_{nl,1,s} (and L_{nl,1}) jumps to approximately 0 from a negative value immediately. Such a sudden voltage jump of L_{nl,1,s} causes the FC3 controller 160 to activate a C_{FC3}-bypassing signal (gating signal) to S₁ at the FC3 120. Since i_{FMS} has not exceeded the negative saturation level of L_{nl,2}, the changing rate of i_{FMS} is limited by L_{nl,2}, which prevents i_{FMS} decreasing too fast and therefore avoids exceeding the safe opening current range of the mechanical switch 120. Therefore, the FC3 controller 160 has enough time to bypass C_{FC3} and cause i_{FMS} to increase again, i.e., approaching 0 (t_{B3} in FIG. 2B). It is noteworthy that there is some delay between t_{B2} and t_{B3}, i.e., T_{dly} in FIG. 2B. During the i_{FMS} increasing period, IFMs enters the linear region of L_{nl,1} and L_{nl,1,s} again. Similarly, when IFMS reaches the upper limit of the saturation current level of L_{nl,1} and L_{nl,1},s, the voltage across L_{nl,1,s} (and L_{nl,1}) drops immediately to approximately 0 from a positive value (t_{B4} in FIG. 2B) and, furthermore, a C_{FC3}-inserting signal (gating signal) to S₁ at the FC3 120 is activated by the FC3 controller 160 to suppress i_{FMS} to 0 again (B5 in FIG. 2B).

To prevent inserting extra stray inductance into the fault current commutation loop during the T_{comm} period, the configuration of a straight conductor with toroidal core, as illustrated in FIG. 1, is selected. In various embodiments, L_{nl,1} and L_{nl,s} use the same types of magnetic core and L_{nl,2} another type. As a voltage sampler, L_{nl,s} can correspond to one core to fit the voltage range of the FC3 controller 160 as much as possible. In various embodiments, the number of cores for L_{nl,1} is optimized based on the MOSFET switching periods, energy stored in the inductor, and requirements for the length of the zero-current period. The number of cores for L_{nl,2} needs to ensure that the FC3 controller 160 and gate driver of the FC3 120 have enough time to respond to the current variation and minimize their stored energy. The voltage based current sensing mechanism of the FC3 controller 160 provides very fast responses and enables controlling the current.

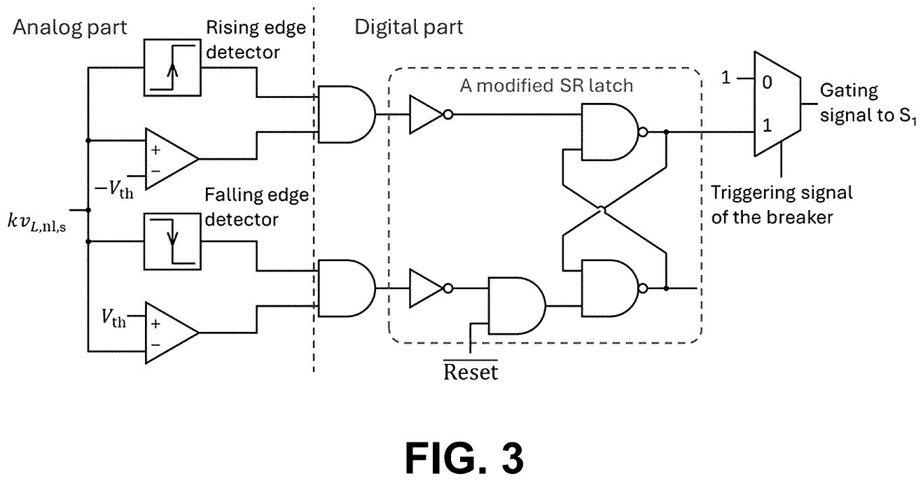

To implement the control strategy mentioned above, a voltage based current sensing mechanism for the FC3 controller 160 has been developed whose diagram is illustrated in FIG. 3, in accordance with various embodiments. In the diagram of FIG. 3, V_{Lnl,s} is the voltage across the sampled nonlinear inductor, L_{nl,s}, k is the scaling factor of a voltage divider, and Vₜₕ is a small voltage to detect if the voltage is non-negative or non-positive. In various embodiments, discrete devices may be used for the control logic. As a part of the whole design program of the breaker, the digital part can also be implemented in a complex programmable logic device (CPLD) or even a field programmable gate array (FPGA).

The diagram and parameters of a target system are provided in FIG. 1 and Table I (below), respectively.

TABLE I

| | | | |
|---|---|---|---|
| Parameters | Value | Parameters | Value |

| | | | | | |
|---|---|---|---|---|---|
| Cₛ | 560 | μF | C_{FC3} | 3.2 | mF |
| Lₛ | 300 | μH | V_{CFC3, 0} | 400 | V |

| | | |
|---|---|---|
| V_{Cs0} | 3 | kV |

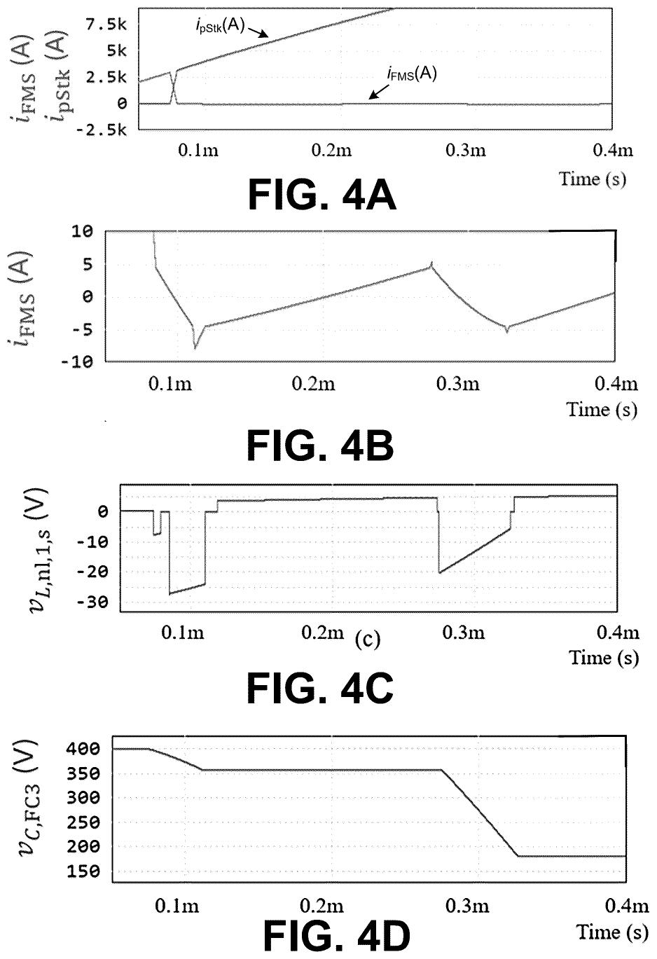

FIGS. 4A-4D demonstrate simulation results of a fault current commutation process based on the disclosed current sensing techniques. FIG. 4A illustrates the currents through the mechanical switch 120 and power stack 140 respectively, which shows that the large fault current is transferred from the mechanical switch 120 to the power stack 140 successfully. FIG. 4B shows details of the current through the mechanical switch 120, FIG. 4C illustrates the details of the voltage across L_{nl,s}, i.e., the sampled voltage part of the nonlinear inductors, and FIG. 4D shows the voltage across C_{FC3}, which verifies the active fault current commutation strategy using the disclosed current sensing techniques.

Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

It is also understood that this disclosure is not limited to the specific devices, methods and conditions or parameters described and/or shown herein, and that the terminology used herein is for the purpose of describing particular embodiments by way of example only and is not intended to be limiting of the claimed disclosure. Also, as used in the specification including the appended claims, the singular forms “a,” “an,” and “the” include the plural, and reference to a particular numerical value indicates at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

Unless defined otherwise, all technical and scientific terms used herein have the same meaning as commonly understood by one of ordinary skill in the art to which this disclosure belongs.

It should be emphasized that the above-described embodiments of the present disclosure are merely possible examples of implementations, merely set forth for a clear understanding of the principles of the disclosure. Many variations and modifications may be made to the above-described embodiment(s) of the present disclosure without departing substantially from the spirit and principles of the disclosure. All such modifications and variations are intended to be included herein within the scope of this disclosure and the present disclosure.

Therefore, at least the following is claimed:

1. A circuit system comprising:
a voltage source coupled to a power circuit, wherein the power circuit includes a fault management system having a mechanical switch that is triggered in response to a fault condition;
the power circuit further including a fault current commutation circuit having one or more nonlinear inductors in series with the fault management system, a pre-charged capacitor insertion circuit, and a controller configured to sample a voltage across one of the one or more nonlinear inductors and supply a gating signal to the pre-charged capacitor insertion circuit, wherein the controller causes the gating signal to activate when the sampled voltage rises from a negative value to approximately 0 or drops from a positive value to approximately 0.

2. The circuit system of claim 1, wherein the fault current commutation circuit further comprises a power stack comprising a series of modules of parallel insulated-gate bipolar transistors (IGBT) and/or metal oxide varistors (MOV).

3. The circuit system of claim 1, wherein the pre-charged capacitor insertion circuit comprises one or more MOSFET switches, diode(s), and/or capacitor components.

4. The circuit system of claim 1, wherein the one or more nonlinear inductors include a first nonlinear inductor, a sampled nonlinear inductor, and a second nonlinear inductor.

5. The circuit system of claim 4, wherein the first nonlinear inductor and the sampled nonlinear inductor have a same saturation current level.

6. The circuit system of claim 5, wherein the second nonlinear inductor has a saturation current level that is greater than the first nonlinear inductor and the sampled nonlinear inductor.

7. The circuit system of claim 6, wherein the rise in voltage across the sampled nonlinear inductor from the negative value to approximately 0 indicates the current flowing through the fault management system is lower than a negative saturation level of the first nonlinear inductor and the sampled nonlinear inductor.

8. The circuit system of claim 7, wherein the drop in voltage across the sampled nonlinear inductor from the positive value to approximately 0 indicates that the current flowing through the fault management system is reaching an upper limit of a saturation current level of the first nonlinear inductor and the sampled nonlinear inductor.

9. The circuit system of claim 1, wherein the controller comprises discrete hardware logic components.

10. The circuit system of claim 1, wherein the controller comprises a complex programmable logic device or a field programmable array.

11. A method for short-circuit fault management comprising:
providing a hybrid DC circuit breaker having a mechanical switch that is triggered in response to a fault condition, wherein the hybrid DC circuit breaker is coupled to a voltage source;
providing a fault current commutation circuitry in series with the mechanical switch, wherein the fault commutation circuitry comprises a power stack of parallel insulated-gate bipolar transistors and/or metal oxide varistors in series with one or more non-linear inductors and at least one MOSFET switch, wherein the fault commutation circuitry further comprises a pre-charged capacitor in parallel with the at least one MOSFET switch;
discretely sampling, by a controller, a voltage across the one or more non-linear inductors and supplying a sample voltage value to the controller;
detecting, by the controller, a fault condition in the fault current commutation circuitry based on the sampled voltage value;
activating the power stack of parallel insulated-gate bipolar transistors and/or metal oxide varistors;
regulating, by the controller, a current value of current flowing through the mechanical switch to be at or approximately zero by controlling activation of the at least one MOSFET switch; and
signaling, by the controller, the mechanical switch to open.

12. The method of claim 11, wherein the controller supplies a gating signal to the pre-charged capacitor insertion circuit when the sampled voltage value rises from a negative value to approximately 0 or drops from a positive value to approximately 0.

13. The method of claim 11, wherein the one or more nonlinear inductors comprise a first nonlinear inductor, a sampled nonlinear inductor, and a second nonlinear inductor in series, wherein the first and sampled nonlinear inductors have a same type of magnetic core and the second nonlinear inductor has a different type of magnetic core.

14. The method of claim 11, wherein the one or more nonlinear inductors comprise a first nonlinear inductor, a sampled nonlinear inductor, and a second nonlinear inductor in series, wherein the first and sampled nonlinear inductors have the same saturation current level which is lower than a saturation current level of the second nonlinear inductor.

15. The method of claim 14, wherein the controller supplies a gating signal to the pre-charged capacitor insertion circuit when the controller determines that a current flowing through the nonlinear inductors is lower than a negative saturation level of the first and sampled nonlinear inductors.

16. The method of claim 15, wherein the current flowing through the nonlinear inductors does not exceed a negative saturation level of the second nonlinear inductor.
